(19) United States
(12) Patent Application Publication
(10) Pub. No.: US 2026/0160843 A1
(43) Pub. Date: Jun. 11, 2026

(54) Method for Operating a Magnetic Resonance Imaging Device, Magnetic Resonance Imaging Device, Computer Program and Electronically Readable Storage Medium

(71) Applicants: Siemens Healthineers AG, Forchheim (DE); King's College London, London (GB)

(72) Inventors: Sarah McElroy, London (GB); Raphael Tomi-Tricot, SCEAUX (FR); Radhouene Neji, London (GB)

(73) Assignees: Siemens Healthineers AG, Forchheim (DE); King's College London, London (GB)

(21) Appl. No.: 19/177,848

(22) Filed: Apr. 14, 2025

(30) Foreign Application Priority Data
Apr. 15, 2024 (EP) 24170237.2

(51) Int. Cl. G01R 33/563; G01R 33/48; G01R 33/561; G01R 33/567

(52) U.S. Cl. CPC G01R 33/56341; G01R 33/4822; G01R 33/5616; G01R 33/5676

(57) ABSTRACT

The disclosure relates to a method for operating a magnetic resonance imaging device for diffusion imaging in an acquisition volume of a patient. A magnetic resonance sequence may be used to acquire magnetic resonance diffusion data, where the acquisition volume is divided into partitions in a partition direction. The magnetic resonance sequence may include, in a repetition for each partition: a diffusion preparation module including at least one tip-down radio frequency pulse and at least one diffusion gradient pulse group following the tip-down pulse, and a three-dimensional gradient echo readout module. The tip-down radio frequency pulse may be slab-selective by applying a slab selection gradient pulse in a phase-encoding direction and the three-dimensional gradient echo module only covers the slab excited by the tip-down radio frequency pulse in the phase-encoding direction.

### CROSS REFERENCE TO RELATED APPLICATIONS

This patent application claims priority to European Patent Application No. 24170237.2, filed Apr. 15, 2024, which is incorporated herein by reference in its entirety.

### BACKGROUND

### Field

The disclosure concerns a method for operating a magnetic resonance imaging device, wherein, for diffusion imaging in an acquisition volume of a patient, a magnetic resonance sequence is used to acquire magnetic resonance diffusion data in k-space. The magnetic resonance diffusion data may be acquired in at least one repetition, the magnetic resonance sequence may include in each repetition: a diffusion preparation module, comprising at least one tip-down radio frequency pulse, at least one tip-up radio frequency pulse and at least one diffusion gradient pulse group between the tip-down pulse and the tip-up pulse, and a readout module.

The disclosure further concerns a magnetic resonance imaging device, a computer program, and an electronically readable storage medium.

### Related Art

Magnetic resonance imaging (MRI) is a well-known and often-used medical imaging modality. Different aspects of acquisition volumes in a human or animal body may be the subject of the examination by applying different weightings during imaging. A corresponding magnetic resonance sequence is chosen. “Classical” known and used weightings comprise T1 weighting, T2 weighting, T2* weighting and proton density weighting.

Diffusion-weighted imaging (DWI) allows acquiring magnetic resonance diffusion data describing the molecular function and micro-architecture of the body and is an important addition to the above-mentioned weightings. In principle, signal contrast is generated based on the difference of Brownian motion of water molecules by measuring the properties of spins of protons bound in water (“water spins”). For example, diffusion coefficient maps, in particular regarding the apparent diffusion coefficient, can be reconstructed from magnetic resonance diffusion data.

The basic principle of diffusion imaging is to apply symmetric, strong diffusion-sensitizing gradients (often shortly “diffusion gradients”) on either side of a 180° refocusing radio frequency pulse after spins have been excited by a tip-down pulse. The phases of stationary spins are not affected by the pair of diffusion gradients. If, however, spins have moved to a different location between the diffusion gradients due to diffusion, they are differently affected and hence fall out of phase, leading to signal loss. After such a diffusion preparation module has been played out, a readout module (image acquisition module) is used to acquire the magnetic resonance diffusion data.

Several applications of diffusion weighted imaging, such as for surgical planning, radiotherapy planning and monitoring of treatment response, require accurate geometric fidelity. Conventional diffusion weighted imaging, which uses a diffusion preparation module with diffusion-sensitizing gradients combined with a two-dimensional spin-echo single-shot echo planar imaging (SS-EPI) readout module, suffers from spatial distortions, especially for high resolution acquisitions and at higher main field strengths, for example 3T or more.

A diffusion-preparation module has been combined with a turbo spin echo (TSE) or balanced steady-state free precession (bSSFP) readout module for distortion-free diffusion imaging, however, such acquisitions suffer from specific absorption rate (SAR) limitations, especially at high main field strength, for example 3T or above. Diffusion preparation modules have also been combined with low SAR T1 gradient-echo readout modules. However, a relatively long readout duration is required, resulting in increased T1 contamination of the acquired magnetic resonance signal. Furthermore, a robust correction for motion-induced magnitude and phase errors has not been provided in the known gradient echo approaches.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 is a sequence diagram of a magnetic resonance sequence according to one or more exemplary embodiments.

FIG. 2 is a flowchart of a method according to one or more exemplary embodiments of the disclosure.

FIG. 3 shows a magnetic resonance imaging device according to one or more exemplary embodiments of the disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

It is an object of the present disclosure to provide a diffusion prepared imaging approach providing high geometric fidelity and data quality, preferably at low specific absorption rate.

This object is achieved by providing an, in particular computer-implemented, method, a magnetic resonance imaging device, a computer program and an electronically readable storage medium according to the disclosure.

In a method as initially described, according to the disclosure, the tip-down radio frequency pulse is slab-selective by applying a first slab selection gradient pulse in a phase-encoding direction.

Here, as usual, the partition encoding direction (usually y) is perpendicular to the phase encoding direction (usually z). The readout direction (frequency encoding direction, usually x) is perpendicular to both the phase encoding direction and the partition encoding direction. As principally known, the three-dimensional k-space to be sampled, in particular the sampling positions, and hence the magnetic resonance diffusion data in k-space, may be acquired in one single repetition or may be divided into subsets each acquired in one of multiple repetitions (shots). In each repetition, which may comprise a diffusion preparation module and a readout module, magnetic resonance diffusion data are acquired for the whole k-space to be sampled or one subset. For example, 10 to 100 subsets may be used, also defining the number of required repetitions. It is noted, that, as usual, multiple magnetic resonance diffusion data sets may be acquired for different b values. A b=0 data set may be acquired by leaving out the diffusion gradient pulse group.

In an exemplary embodiment, at the beginning of the diffusion preparation module, a saturation pulse, in particular a fat saturation radio frequency pulse, is output to saturate the magnetization of spins which are not of interest, in particular non-water spins (that is, spins of protons not bound in water). Of course, other fat saturation and fat suppression techniques may also be employed.

The diffusion gradient pulse group may comprise at least one diffusion gradient pulse and at least one refocusing, in particular 180°, radio frequency pulse. As further discussed below, the concrete structure of the diffusion gradient pulse group may preferably be chosen to suppress artifacts, in particular by suppressing eddy currents, reducing spatial distortion and the like, to allow best image quality regarding these aspects.

The tip-down radio frequency pulse preferably has a flip angle of 90° (90 ° tip-down pulse). It is applied slab selectively, that is, it is output simultaneously with a slab selection gradient pulse in the phase encoding direction. Hence, excitation is restricted spatially to the spins of interest, in particular spins of protons bound in water (“water spins”) if fat suppression or saturation has been applied. The field of view is hence reduced in the phase-encoding direction, such that the approach described here may be called a reduced field of view (rFOV) approach. In preferred embodiments, where the readout module is three-dimensional, the readout module may also be slab-selective by applying a second slab selection gradient pulse in a partition encoding direction, which is orthogonal to the phase-encoding direction. Hence, also in the phase encoding direction, the field of view can be reduced. In such a case, of course, the readout module may still comprise phase encoding gradients and respective rewinder gradients in the partition encoding direction in addition to the second slab selection gradient.

The diffusion preparation module also, as known, may comprise at least one tip-up radio frequency pulse succeeding the diffusion gradient pulse group. The tip-up radio frequency pulse may correspond to the tip-down radio frequency pulse, in particular at least regarding the flip angle. A slab selectivity for the tip-up radio frequency pulse is not required. Hence, the tip-up radio frequency pulse is preferably non-selective. The tip-up radio frequency pulse may preferably be followed by a spoiler gradient pulse which dephases any remaining transverse magnetisation from spins outside the reduced field of view.

Reducing the field of view in the phase encoding direction allows to use shorter readout modules, since the number of phase encoding steps in the readout module can be reduced to fit the reduced field of view. For example, half as many or even less than half as many phase encoding steps as used without slab selectivity of the tip-down radio frequency pulse may be required, This allows to reduce the duration of the readout module, thereby increasing relative diffusion weighting and reducing T1 contamination. This is especially advantageous for three-dimensional readout modules, but can also be applied to two-dimensional readout modules. In preferred embodiments, the readout module may be a gradient echo (GRE) readout module. In this manner, the advantages of the gradient echo readout, in particular its low SAR, may be utilized.

In summary, the diffusion preparation module is combined with a two-dimensional or, preferably, three-dimensional readout module, wherein the tip-down radio frequency pulse of the diffusion preparation module is applied simultaneously with a slab-selective gradient (of the slab selection gradient pulse) in the phase-encoding direction, thereby restricting excitation to a reduced field of view, namely the slab, in this direction, and hence allowing for a reduced readout time which results in lower T1 contamination and higher relative diffusion weighting. The magnetic resonance sequence described here can be understood as an, in particular three-dimensional, reduced field of view diffusion-prepared magnetic resonance imaging sequence.

In preferred embodiments, the readout module uses a centric encoding scheme in the phase-encoding direction, in particular starting at the central k-space line in the phase-encoding direction. Hence, the most central k-space line, where most of the signal is found, is acquired first, such that its magnetic resonance diffusion data has the most diffusion weighting and is least affected by possible T1 contamination. This further reduces this effect and improves diffusion data quality. In particular, cartesian sampling may be used. For example, for each repetition, an excitation radio frequency pulse is played out, in particular during respective second slab-selection gradient pulses in the partition encoding direction. The excitation radio frequency pulse may be followed by pairs of phase encoding gradient pulses and phase rewinder gradient pulses both for the phase encoding direction and the partition encoding direction. A readout gradient pulses is output in a readout direction perpendicular to both the phase encoding direction and the partition encoding direction between the respective phase encoders and rewinders.

As already discussed, a tip-up radio frequency pulse is used following the diffusion gradient group in the diffusion preparation module. In an exemplary embodiment, the tip-up radio frequency pulse is preceded by a magnetization stabilizer gradient pulse, in particular in the partition encoding direction, of the diffusion preparation module and the readout module may comprise a stabilizer rewinding gradient pulse in the stabilization direction output after each excitation radio frequency pulse of the readout module. The stabilizer rewinding gradient pulse has opposing polarity regarding the magnetization stabilizer gradient pulse. Magnitude stabilization techniques are known in the art for other applications and solve the problem of unknown phases of the transverse magnetization before applying a radio frequency pulse, in this case the tip-up radio frequency pulse. Depending on the phase position, the radio frequency pulse may affect all from no magnetization to the whole magnetization. By dephasing the spins using the magnetization stabilizer gradient, at least half of the spins are reliably affected, leading to magnitude stabilization. However, to revert phase-induced magnitude inconsistencies, that would normally occur after the diffusion preparation module, back into phase inconsistencies, the stabilizer rewinding gradient pulses are applied during the readout module for each excitation radio frequency pulse. However, these stabilizer rewinding gradient pulses also act as a spoiler gradient for the magnetization in the outer volume, that is, outside the slab, suppressing unwanted signals. In concrete embodiments, the magnitude stabilizer gradient pulse may be output following the diffusion gradient pulse group.

In principle, the magnitude stabilizer gradient pulse can be output in any direction. In an exemplary embodiment, the magnitude stabilizer gradient pulse is output in the partition encoding direction and the stabilizer rewinding gradient pulse is included in a phase encoding gradient pulse in the partition encoding direction associated with the excitation radio frequency pulse. For example, the partition stabilizer rewinding gradient can be incorporated into the phase encoding gradient as an additional moment, corresponding to the moment of the magnitude stabilizer gradient pulse. In this manner, no additional gradient pulse is required.

As already noted, in an exemplary embodiment, a spoiler gradient pulse is applied, for example in the partition encoding direction, between the tip-up radio frequency pulse and the gradient echo readout module. Such a spoiler gradient pulse acts to dephase any remaining transverse magnetization, including in the outer volume and/or of non-water spins, for example those of protons bound in fat.

In preferred embodiments, each readout module may comprise, at its end, a phase navigator submodule for measuring phase information associated with the respective repetition, wherein the phase information is used to correct the acquired magnetic resonance diffusion data regarding phase offsets between repetitions. Here, if a magnetization stabilizer gradient pulse is used, the stabilizer rewinding gradient pulse is preferably also applied in the phase navigator submodule. Hence, a phase navigator (or phase correction navigator) can be used to keep track of phase and correct any inter-repetition (inter-shot) phase offsets. In an exemplary embodiment, the phase information measured is two-dimensional, in particular comprising the k-space center. A two-dimensional phase navigator can quickly be measured and, in particular if placed in the k-space center, yields all required information in evaluable form. The two-dimensional phase navigator may preferably be linearly encoded. The phase information may be repetition-wise applied to correct phase offsets between repetitions. In an exemplary embodiment, the phase information may be determined for each receiving coil element by applying an inverse Fourier transform to the navigator data set acquired in a respective repetition. A Hamming filter may then be applied to the transformed navigator data set to determine the phase information. To correct, an inverse Fourier transform is applied to the magnetic resonance diffusion data subset of the respective repetition and receiving coil element. The phase information is applied as a correction to the transformed subset. To transform the corrected data back into k-space, a Fourier transform is applied to the corrected subset. All corrected magnetic resonance diffusion data subsets for each receiving coil element and repetition then form the corrected magnetic resonance diffusion data set, from which, for example, a diffusion weighted image, a diffusion coefficient map and the like can be reconstructed.

In an exemplary embodiment, the slab dimension in the phase encoding direction is chosen to cover a whole region of interest of the acquisition volume. Hence, only one slab has to be acquired. It is, however, also conceivable to define two or more slabs covering the region of interest and acquire their respective magnetic resonance diffusion data in successive imaging processes, each using the magnetic resonance sequence as described above with accordingly chosen slab selection gradient pulses. If a reduced field of view is also used in the partition encoding direction, the slab dimension in the partition encoding direction may also be chosen to cover the whole region of interest of the acquisition volume.

Regarding the diffusion gradient group, many known concrete configurations may be employed. Diffusion gradient groups have been optimized in the art, in particular regarding eddy currents and reduction of spatial distortion artifacts. For example, bipolar diffusion gradient pulses may be used and twice-refocused techniques may be applied. In preferred embodiments of the disclosure, a bipolar twice-refocused diffusion preparation may be used, significantly reducing spatial distortion artifacts and hence further improving spatial accuracy. In these embodiments, the diffusion gradient group may comprise a pair of bipolar diffusion gradient pulses, each surrounding a 180° adiabatic refocusing radio frequency pulse. The refocusing radio frequency pulse is output between the two sub-pulses of opposite polarity of the bipolar diffusion gradient pulse, in particular at zero gradient strength of the bipolar diffusion gradient pulse. However, as mentioned, other diffusion preparation techniques may also be employed.

The combination of slab-selectivity in the phase encoding direction, allowing shorter gradient echo readout modules, with magnitude stabilization, a phase navigator and in particular also a diffusion preparation scheme reducing geometric distortion synergize to allow a diffusion magnetic resonance measurement with especially high overall diffusion data quality, and, in particular, high geometric fidelity and accuracy. If a gradient echo readout is used, a low SAR may also be achieved.

The disclosure also concerns a magnetic resonance imaging device, comprising a controller having an acquisition unit, wherein the acquisition unit is configured, for diffusion imaging in an acquisition volume of a patient, to use a magnetic resonance sequence to acquire magnetic resonance diffusion data in k-space in at least one repetition, the magnetic resonance sequence comprising, in each repetition:
a diffusion preparation module, comprising at least one tip-down radio frequency pulse, at least one tip-up radio frequency pulse and at least one diffusion gradient pulse group between the tip-down radio frequency pulse and the tip-up radio frequency pulse, and
a readout module,

wherein the acquisition unit is further configured to apply the tip-down radio frequency pulse slab-selectively by using a first slab selection gradient pulse in a phase-encoding direction. All remarks and features regarding the method according to the disclosure can analogously be applied to the magnetic resonance imaging device of the disclosure and vice versa, such that the same advantages may be achieved.

The controller may comprise at least one processor and at least one storage means. Functional units may be implemented by hardware and/or software, comprising an acquisition unit to control acquisition equipment of the magnetic resonance imaging device to acquire magnetic resonance data, in particular magnetic resonance diffusion data using the magnetic resonance sequence as described above. In particular, the magnetic resonance imaging device may comprise a main magnet unit comprising a main magnet, which generates a main magnetic field in a bore of the main magnet unit. The acquisition equipment may comprise at least one gradient coil assembly to output gradient pulses and at least one radio frequency coil assembly to output radio frequency pulses and/or receive magnetic resonance signals. At least one radio frequency coil assembly may comprise multiple coil elements, which may be used independently for transmitting and/or receiving.

A computer program according to the disclosure may comprise program means such that, when the computer program is executed on a controller of a magnetic resonance imaging device, the controller is caused to perform a method according to the disclosure. The computer program may be stored on an electronically readable storage medium according to the disclosure, which hence may comprise control information stored thereon, which may comprise a computer program according to the disclosure and is configured such that, when the storage medium is used in a controller of a magnetic resonance imaging device, the controller is configured to perform a method according to the disclosure. The electronically readable storage medium may be a non-transitory medium, for example a CD ROM.

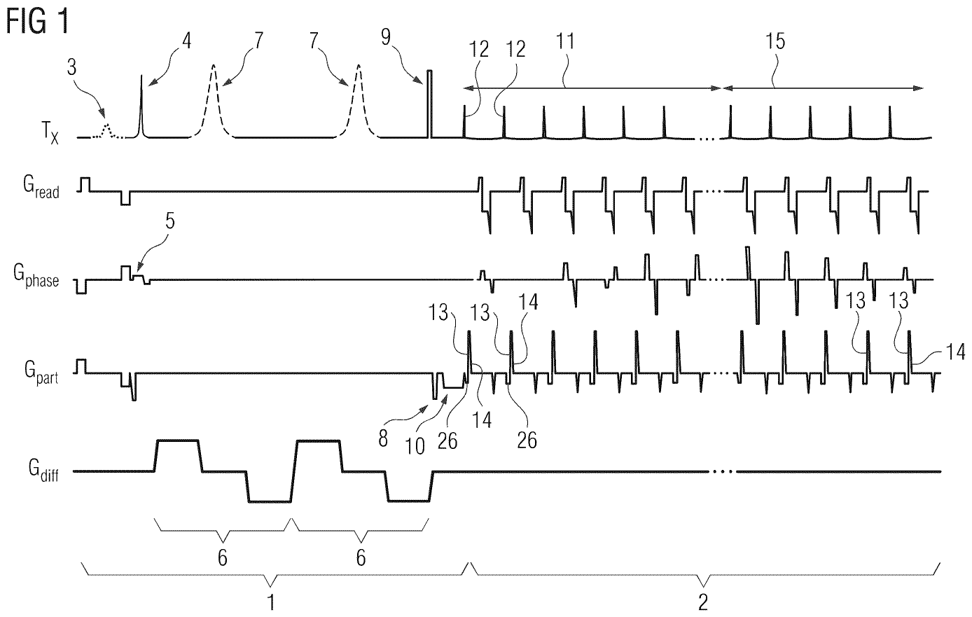

FIG. 1 shows a sequence diagram of one repetition of a magnetic resonance sequence to be used in a method according to the disclosure. The uppermost graph shows radiofrequency activity (Tx), the next gradient activity in a readout direction (G_{read}), the middle graph gradient activity in a phase encoding direction (Pₚₕₐₛₑ), the next-to-lowest graph gradient activity in a partition encoding direction (Gₚₐᵣₜ) and the final graph diffusion gradient activity (G_{diff}). In the following, not all radio frequency pulses and gradient pulses will be discussed in detail, but the focus will be on the relevant design regarding optimized diffusion data quality, in particular regarding geometric fidelity and accuracy, while minimizing SAR and T1 contamination and maximizing diffusion weighting. In the current example, the used magnetic resonance imaging device provides a main magnetic field of 3T or more. The magnetic resonance sequence uses a twice-refocused bipolar diffusion preparation scheme combined with a gradient echo readout, followed by a two-dimensional phase correction navigator.

In each repetition, as shown in FIG. 1, a subset of the k-space to be acquired is three-dimensionally measured using respective encoding, in particular phase encoding steps. For example, 10 to 100 encodings and hence repetitions can be used. The sequence described here can, of course, also be applied in the case of a single repetition. Each repetition, as shown in FIG. 1, comprises a diffusion preparation module 1 and a readout module 2. At the beginning of the diffusion preparation module, a fat saturation radio frequency pulse 3 (accompanied by respective gradient pulses) is output to saturate fat spins, such that the diffusion of water can be reliably measured by receiving signals from water spins.

Immediately after the fat saturation radio frequency pulse 3, a 90° tip-down radio frequency pulse 4 is output simultaneously with a slab selection gradient pulse 5, such that the 90° tip-down radio frequency pulse 4 only acts on a certain slab, which, in this case, covers the whole region of interest, that is, the relevant acquisition volume, in the phase encoding direction. Hence, by slab selectivity, a reduced field of view is excited. The diffusion preparation group following the excitation may comprise a pair of bipolar diffusion gradient pulses 6, each surrounding a 180° adiabatic refocusing radio frequency pulse 7.

A magnitude stabilizer gradient pulse 8 is applied in the partition encoding direction directly before a non-selective tip-up radio frequency pulse 9 to fully dephase spins across the selected slab. Following the tip-up radio frequency pulse 9, a spoiler gradient pulse 10 is applied to dephase any remaining transverse magnetization, including in the outer volume (outside the selected slab) and/or fat spins.

The readout module 2 may comprise gradient echo readout submodules in a first time interval 11 for each k-space phase encoding line to be acquired, wherein centric encoding is used regarding the order of the phase encoding lines. A magnitude stabilizer rewinder gradient pulse is played out after each excitation radio frequency pulse 12, thereby reverting phase-induced magnitude inconsistencies back into phase inconsistencies. In this embodiment, the stabilizer rewinder gradient pulse is incorporated as additional moment 13 into phase encoding gradient pulses 14. Also, in this embodiment, with each excitation radio frequency pulse 12, second slab selection gradient pulses 26 are output, which provide slab-selectivity also in the partition encoding direction. Due to the centric encoding, most of the signal is acquired with maximized diffusion weighting and almost no T1 contamination. The gradient echo readout is shortened compared to a non-slab-selective excitation, further preventing T1 contamination, yet still covering the required range in phase-encoding direction.

After the first time interval 11, in a second time interval 15 of the readout module 2, a two-dimensional phase correction navigator is acquired in a phase navigator submodule. Here, of course, the stabilizer rewinder gradient pulses are still applied. Phase information determined from phase navigator data sets for partitions and each receiving coil element is used to correct the respective magnetic resonance diffusion data subsets of the respective partition and receiving coil element. An inverse Fourier transform is applied to each phase navigator data set, followed by a Hamming filter to determine phase information. An inverse Fourier transform is then applied to each magnetic resonance diffusion data subset, followed by a phase correction using the phase information for each receiving coil element. A Fourier transform is then applied to the corrected magnetic resonance diffusion data subset. In this manner, inter-repetition phase inconsistencies are corrected.

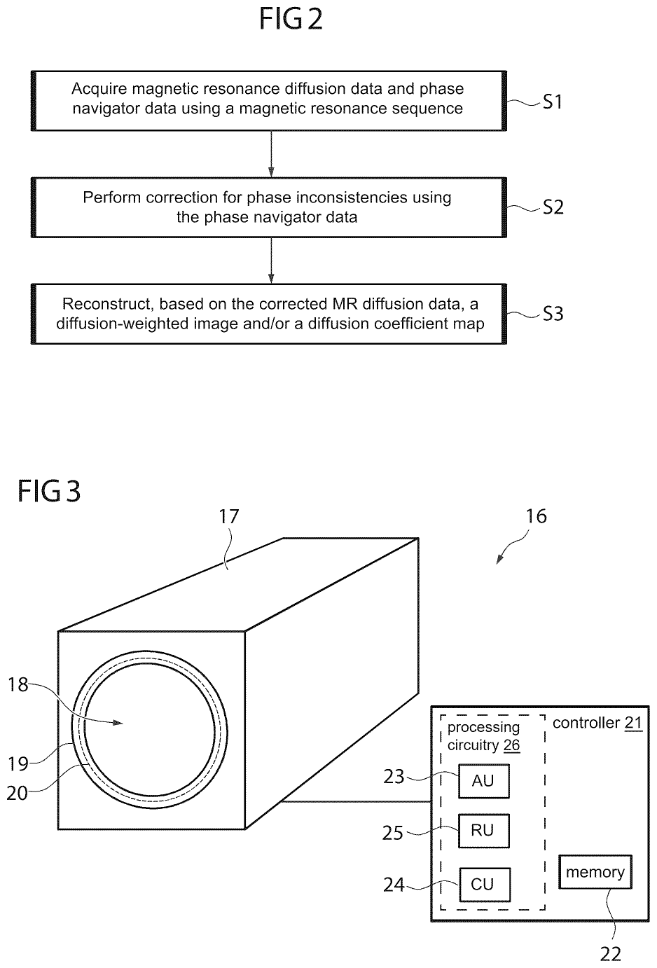

FIG. 2 shows a flowchart of a method according to the disclosure. In a step S1, magnetic resonance diffusion data and phase navigator data are acquired using the magnetic resonance sequence of FIG. 1. In a step S2, correction for phase inconsistencies is performed using the phase navigator data. Hence, in a step S3, based on the corrected magnetic resonance diffusion data, a diffusion-weighted image, a diffusion coefficient map and the like can be reconstructed.

FIG. 3 schematically shows a magnetic resonance imaging device 16 according to the disclosure. The magnetic resonance imaging device 16 may comprise a main magnet unit (scanner) 17 housing a main field magnet (not shown), in this case generating a main magnetic field of 3T or more. The main magnet unit 17 may comprise a bore 18, into which a patient can be introduced using a patient table (not shown). Surrounding the bore, a gradient coil assembly 19 and a radio frequency coil assembly 20 are indicated. Local coils may, of course, also be used.

The operation of the magnetic resonance imaging device 16 is controlled by a control device (controller) 21, whose functional structure is indicated. The controller 21 may comprise a storage means (memory) 22 for storing data, for example magnetic resonance diffusion data and phase navigator data, and/or executable instructions (e.g., computer program). The controller 21 may comprise processing circuitry 26 that is configured to perform one or more functions and/or operations of the controller 21. For example, the processing circuitry 26 may execute instructions stored in memory 22 to perform one or more aspects of the controller 21.

The controller 21 may comprise acquisition unit 23, correction unit 24, and a reconstruction unit 25. The acquisition unit 23 may be configured to control the acquisition equipment comprising coil assemblies 19, 20 to output pulses according to magnetic resonance sequences, in particular also the one shown in FIG. 1 for diffusion imaging according to step S1. The correction unit 24 may be configured to perform/apply a correction, such as the correction according to step S2. The reconstruction unit 25 configured to reconstruct magnetic resonance images and/or maps, such as according to step S3. In an exemplary embodiment, the acquisition unit 23, correction unit 24, and a reconstruction unit 25 are components (e.g., modules) of the processing circuitry 26. The controller 21 may include an input/output (I/O) interface configured to communicatively couple the controller 21 to the scanner 17 and/or one or more other components of the magnetic resonance imaging device 16. The controller 21 may be at least partially integrated into the scanner 17. In other aspects, the controller 21 may be physically separate component of the magnetic resonance imaging device 16.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein. In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for operating a magnetic resonance imaging device for diffusion imaging in an acquisition volume of a patient, the method comprising:
providing a magnetic resonance sequence; and
acquiring, at least in one repetition and using the magnetic resonance sequence, magnetic resonance diffusion data in k-space, wherein magnetic resonance sequence comprises, for each repetition:
a diffusion preparation module comprising at least one tip-down radio frequency pulse, at least one tip-up radio frequency pulse, and at least one diffusion gradient pulse group between the tip-down radio frequency pulse and the tip-up radio frequency pulse; and
a readout module, wherein the tip-down radio frequency pulse is slab-selective by applying a first slab selection gradient pulse in a phase-encoding direction.

2. The method according to claim 1, wherein the readout module uses a centric encoding scheme starting at the k-space center in the phase encoding direction.

3. The method according to claim 1, wherein the tip-up radio frequency pulse is preceded by a magnetization stabilizer gradient pulse and the readout module comprises a stabilizer rewinding gradient pulse in a stabilization direction output after each excitation radio frequency pulse of the readout module.

4. The method according to claim 3, wherein the magnetization stabilizer gradient pulse follows the diffusion gradient pulse group.

5. The method according to claim 3, wherein the magnetization stabilizer gradient pulse is output in a partition encoding direction and the stabilizer rewinding gradient pulse is included in a phase encoding gradient pulse in the partition encoding direction associated with the excitation radio frequency pulse.

6. The method according to claim 1, wherein a spoiler gradient pulse is applied between the tip-up radio frequency pulse and the readout module.

7. The method according to claim 1, wherein the readout module comprises, at its end, a phase navigator submodule configured to measure phase information associated with the respective repetition, the phase information being configured to correct the acquired magnetic resonance diffusion data regarding phase offsets between repetitions.

8. The method according to claim 7, wherein, in response to a magnetization stabilizer gradient pulse, also applying the stabilizer rewinding gradient pulse in the phase navigator submodule.

9. The method according to claim 7, wherein the measured phase information is two-dimensional.

10. The method according to claim 9, wherein comprises the k-space center.

11. The method according to claim 1, wherein a slab dimension in the phase encoding direction is selected to cover an entirety of a region of interest of the acquisition volume.

12. The method according to claim 1, wherein the readout module is three-dimensional and/or a gradient echo readout module.

13. A non-transitory computer-readable storage medium with an executable program stored thereon, that when executed, instructs a processor to perform the method of claim 1.

14. A magnetic resonance imaging device, comprising:
a controller configured to:
acquire, based on a magnetic resonance sequence, magnetic resonance diffusion data in k-space in at least one repetition for diffusion imaging in an acquisition volume of a patient, wherein the magnetic resonance sequence comprises, in each repetition: a diffusion preparation module comprising at least one tip-down radio frequency pulse, at least one tip-up radio frequency pulse, and at least one diffusion gradient pulse group between the tip-down radio frequency pulse and the tip-up radio frequency pulse, and a readout module; and
apply the tip-down radio frequency pulse slab-selectively by using a first slab selection gradient pulse in a phase-encoding direction.

15. An apparatus comprising:
one or more processors; and
memory storing instructions that, when executed by the one or more processors, cause the apparatus to:
acquire, at least in one repetition and using a magnetic resonance sequence, magnetic resonance diffusion data in k-space, wherein magnetic resonance sequence comprises, for each repetition:
a diffusion preparation module comprising at least one tip-down radio frequency pulse, at least one tip-up radio frequency pulse, and at least one diffusion gradient pulse group between the tip-down radio frequency pulse and the tip-up radio frequency pulse; and
a readout module, wherein the tip-down radio frequency pulse is slab-selective by applying a first slab selection gradient pulse in a phase-encoding direction.

16. A magnetic resonance device comprising the apparatus of claim 15.

17. The magnetic resonance device according to claim 16, further comprising a magnetic resonance scanner, the apparatus being configured to control the magnetic resonance scanner to acquire the magnetic resonance diffusion data.
